(19) United States
(12) Patent Application Publication
(10) Pub. No.: US 2025/0273563 A1
(43) Pub. Date: Aug. 28, 2025

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Jong Soon PARK, Suwon-si (KR); Hyon Wook RA, Suwon-si (KR); Seo Yeon PARK, Suwon-si (KR); Keun Hee BAI, Suwon-si (KR); Jin Wook LEE, Suwon-si (KR); Ho Bum CHOI, Suwon-si (KR)

(73) Assignee: SAMSUNG ELECTRONICS CO., LTD., Suwon-si (KR)

(21) Appl. No.: 18/923,224

(22) Filed: Oct. 22, 2024

(30) Foreign Application Priority Data
Feb. 27, 2024 (KR) 10-2024-0028107

(51) Int. Cl. H01L 23/522; H01L 21/263; H01L 21/311; H01L 21/768; H01L 29/06

(52) U.S. Cl. CPC H01L 23/5226; H01L 21/2633; H01L 21/31144; H01L 21/76802; H01L 21/76832; H01L 21/76877; H10D 62/121

(57) ABSTRACT

A semiconductor device includes: a first and second connection wirings in a first interlayer insulating film; a second interlayer insulating film on the first interlayer insulating film; a third connection wiring in the second interlayer insulating film; a first connection via connecting the third connection wiring and the first connection wiring; and a second connection via connecting the third connection wiring and the second connection wiring, wherein the third connection wiring includes (i) a first line portion extending in a first direction and comprising a first sidewall and a second sidewall opposite to the first sidewall in a second direction, (ii) a second line portion protruding from the first sidewall of the first line portion in the second direction, and (iii) a first protruding portion protruding from the second sidewall of the first line portion in the second direction.

### CROSS-REFERENCE TO RELATED APPLICATION

This application claims priority from Korean Patent Application No. 10-2024-0028107 filed on Feb. 27, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor device and a method of fabricating the same, and more particularly, to a semiconductor device including wiring lines formed during a back-end-of-line (BEOL) process and a method of fabricating the semiconductor device.

### 2. Description of the Related Art

Due to developments in electronic technology and the recent trend of down-scaling, high integration density and low power consumption designs are required of semiconductor chips. In order to meet these requirements, the feature size of semiconductor devices has continuously decreased.

Particularly, this trend has caused the distances between wires to decrease. However, as the distance between wires continuously decreases, forming wires that remain stably separate from each other becomes more challenging.

### SUMMARY

Aspects of the present disclosure provide a semiconductor device capable of improving device performance and reliability.

Aspects of the present disclosure also provide a method of fabricating a semiconductor device capable of improving device performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the disclosure, a semiconductor device comprises: a first connection wiring and a second connection wiring in a first interlayer insulating film; a second interlayer insulating film on the first interlayer insulating film; a third connection wiring in the second interlayer insulating film; a first connection via connecting the third connection wiring and the first connection wiring; and a second connection via connecting the third connection wiring and the second connection wiring, wherein the third connection wiring comprises (i) a first line portion extending in a first direction and comprising a first sidewall and a second sidewall opposite to the first sidewall in a second direction, (ii) a second line portion protruding from the first sidewall of the first line portion in the second direction, and (iii) a first protruding portion protruding from the second sidewall of the first line portion in the second direction, wherein the second line portion and the first protruding portion are aligned in the second direction, and wherein the first connection via connects the second line portion and the first connection wiring.

According to an aspect of the disclosure, a semiconductor device comprises: an interlayer insulating film; a first connection wiring in the interlayer insulating film; and one or more connection vias in the interlayer insulating film and connected to the first connection wiring, wherein the first connection wiring comprises (i) a first line portion extending in a first direction, (ii) a second line portion and a third line portion, each of which are connected to the first line portion and extend in a second direction, and (iii) a first protruding portion and a second protruding portion, each of which are connected to the first line portion and protrude in the second direction, wherein the second line portion and the first protruding portion are aligned in the second direction, wherein the third line portion and the second protruding portion are aligned in the second direction, wherein the one or more connection vias overlap the second line portion and the third line portion in a third direction, and the one or more connection vias do not overlap the first protruding portion and the second protruding portion in the third direction.

According to an aspect of the disclosure, a method of manufacturing a semiconductor device, comprising: forming an interlayer insulating film on a substrate; forming a hard mask film on the interlayer insulating film; forming, on the hard mask film, a first mask pattern comprising a first opening and a second opening that are spaced apart from each other by a first distance; forming, on the hard mask film using a first etching process that etches the first mask pattern, a second mask pattern that comprises a third opening and a fourth opening that are spaced apart from each other by a second distance that is less than the first distance; forming a hard mask pattern on the interlayer insulating film by patterning the hard mask film using the second mask pattern; and forming a first connection wiring trench and second connection wiring trench in the interlayer insulating film by performing a second etching process using the hard mask pattern, wherein the first mask pattern comprises a first sub-mask pattern and a second sub-mask pattern, which are sequentially stacked on the hard mask film.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail exemplary embodiments thereof with reference to the attached drawings, in which:

FIG. 1 is an example plan view for explaining a semiconductor device according to some embodiments.

FIG. 2 is a cross-sectional view taken along line A-A of FIG. 1, according to some embodiments.

FIG. 3 is a cross-sectional view taken along line B-B of FIG. 1, according to some embodiments.

FIGS. 4 and 5 are a plan view and a cross-sectional view, respectively, for explaining a semiconductor device, according to some embodiments.

FIGS. 6 and 7 are a plan view and a cross-sectional view, respectively, for explaining a semiconductor device, according to some embodiments.

FIG. 8 is a plan view for explaining a semiconductor device, according to some embodiments.

FIG. 9 is a cross-sectional view for explaining a semiconductor device, according to some embodiments of the present disclosure.

FIG. 10 is a cross-sectional view for explaining a semiconductor device, according to some embodiments of the present disclosure.

FIGS. 11 to 13 illustrate a semiconductor device, according to some embodiments of the present disclosure.

FIGS. 14 to 25 are schematic diagrams for explaining intermediate steps of a method of manufacturing a semiconductor device, according to some embodiments.

### DETAILED DESCRIPTION

Hereinafter, exemplary embodiments of the present disclosure will be described with reference to the accompanying drawings. Terms, such as ‘upper,’ ‘upper portion,’ ‘upper surface,’ ‘lower,’ ‘lower portion,’ ‘lower surface,’ ‘side surface,’ and the like, may be understood as referring to the drawings, unless otherwise indicated by reference numerals.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The terms “first direction,” “second direction,” and “third direction,” may refer to directions that are perpendicular to each other. For example, the first direction may be perpendicular to the second and third directions, the second direction may be perpendicular to the first and third directions, and the third direction may be perpendicular to the first and second directions. In one or more examples, with respect to the XYZ axes illustrated in the drawings, the first direction may refer to the X axis, the second direction may refer to the Y axis, and the third direction may refer to the Z axis.

The accompanying drawings illustrate, by way of example, a fin field-effect transistor (FinFET) including a fin pattern-shape channel region, a transistor containing nanowires or nanosheets, a Multi-Bridge Channel field-effect transistor (MBCFET™), and a vertical field-effect transistor (VFET), but are not limited thereto. Semiconductor devices according to some embodiments of the present disclosure may also include a tunneling field-effect transistor (tunneling FET) or a three-dimensional (3D) transistor. Moreover, semiconductor devices according to some embodiments of the present disclosure may include a planar transistor. Additionally, the technical concept of the present disclosure may be applicable to a two-dimensional (2D) material-based FET and a heterostructure thereof. However, as understood by one of ordinary skill in the art, the embodiments of the present disclosure are not limited to these structures, any may be applied to any suitable structure.

Furthermore, semiconductor devices according to some embodiments of the present disclosure may include a bipolar junction transistor and a laterally-diffused metal-oxide semiconductor (LDMOS).

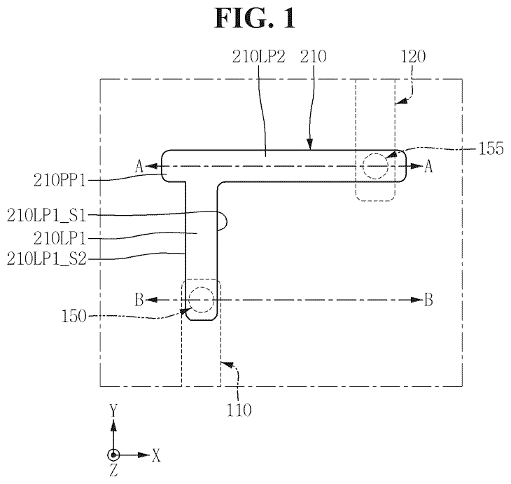

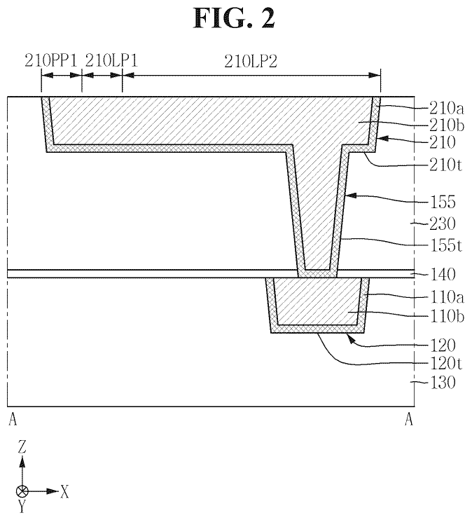

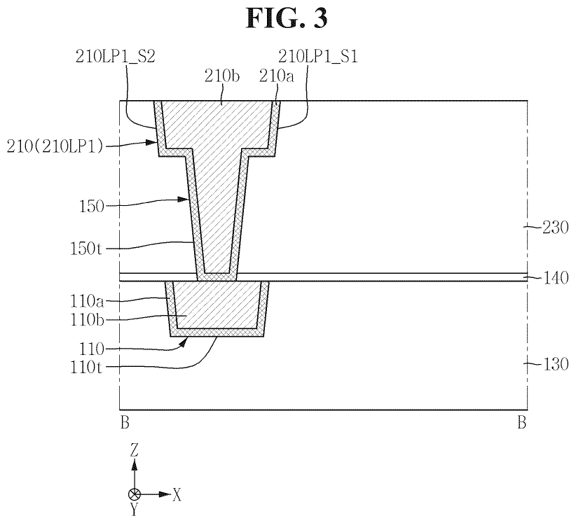

FIG. 1 is an example plan view for explaining a semiconductor device according to some embodiments. FIG. 2 is a cross-sectional view taken along line A-A of FIG. 1. FIG. 3 is a cross-sectional view taken along line B-B of FIG. 1.

Referring to FIGS. 1 to 3, the semiconductor device according to some embodiments may include a first lower connection wiring 110, a second lower connection wiring 120, a first upper connection wiring 210, a first connection via 150, and a second connection via 155.

In one or more examples, as illustrated in FIG. 2, the first and second lower connection wirings 110 and 120 may be disposed within a first interlayer insulating film 130. For example, the first and second lower connection wirings 110 and 120 may extend longitudinally in a second direction (e.g., Y axis).

The first and second lower connection wirings 110 and 120 may have a linear shape extending in the second direction. The second direction may be the length direction of the first and second lower connection wirings 110 and 120, and a first direction (e.g., X axis) may be the width direction of the first and second lower connection wirings 110 and 120. In one or more examples, the first direction intersects the second direction and a third direction (e.g., Z axis). In one or more examples, the second direction intersects the third direction.

In one or more examples, one of the first and second lower connection wirings 110 and 120 may have a linear shape extending in the first direction.

The first interlayer insulating film 130 may cover the gate electrode and source/drain of a transistor formed during a Front-End-Of-Line (FEOL) process. For example, the first interlayer insulating film 130 may be an interlayer insulating film formed during a Back-End-Of-Line (BEOL) process. The first and second lower connection wirings 110 and 120 may be connection wirings formed during the BEOL process. In one or more examples, an FEOL process may be a first of a manufacturing process for semiconductor devices involving the creation of transistors, capacitors, and resistors in a semiconductor substrate. In one or more examples, a BEOL process may be process in semiconductor device fabrication that consists of depositing metal interconnect layers onto a wafer patterned with device. The BEOL process may be the second part of the manufacturing process for semiconductor devices performed after the FEOL process.

In one or more examples, the first and second lower connection wirings 110 and 120 may be contacts or contact wirings formed during a Middle-Of-Line (MOL) process. In one or more examples, the MOL process may be performed between the FEOL and BEOL process. The MOL process may form structures that that serve as contacts between wiring layers or a sources, drain, and gate of a transistor. For convenience, the first and second lower connection wirings 110 and 120 will hereinafter be described as being connection wirings formed during the BEOL process.

In one or more examples, the first interlayer insulating film 130 may include, for example, at least one of silicon oxide, silicon nitride, silicon oxynitride, and a low-k material. The first interlayer insulating film 130 may include a low-k material to reduce a coupling phenomenon between wirings. The dielectric constant of the low-k material is less than 3.9, which is the dielectric constant of silicon oxide.

The low-k material may be, for example, a silicon oxide with appropriately high carbon and hydrogen contents, such as SiCOH. In one or more examples, the low-k material may be a silicon oxide with an appropriately high carbon content, such as SiCO. The low-k material may contain carbon (C). As carbon is contained in an insulating material, the dielectric constant of the insulating material can be lowered. Furthermore, to further reduce the dielectric constant of the insulating material, the insulating material may include pores, such as cavities filled with gas or air.

Examples of the low-k material may include Fluorinated TetraEthylOrthoSilicate (FTEOS), Hydrogen SilsesQuioxane (HSQ), Bis-benzoCycloButene (BCB), MethylSilsesQuioxane (MQS), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), carbon-doped silicon Oxide (CDO), hydrogen-doped silicon oxide, polypropylene oxide, polyimide nanofoam, Organo Silicate Glass (OSG), amorphous fluorinated carbon, silica aerogel, silica xerogel, mesoporous silica, aromatic polymer, and a combination thereof. However, as understood by one of ordinary skill in the art, the present disclosure is not limited to these materials.

In one or more examples, the first and second lower connection wirings 110 and 120 may be disposed at a first metal level. The first interlayer insulating film 130 may include first and second lower wiring trenches 110t and 120t, which extend longitudinally in the second direction.

The first lower connection wiring 110 may be disposed within the first lower wiring trench 110t. For example, the first lower connection wiring 110 fills the first lower wiring trench 110t. The second lower connection wiring 120 may be disposed within the second lower wiring trench 120t. For example, the second lower connection wiring 120 may fills the second lower wiring trench 120t.

Each of the first and second lower connection wirings 110 and 120 may include a lower wiring barrier film 110a and a lower wiring fill film 110b. The lower wiring fill film 110b may be disposed on the lower wiring barrier film 110a.

For example, each of the first and second lower connection wirings 110 and 120 may include a plurality of conductive films. Each of the first and second lower connection wirings 110 and 120 may have a multi-conductive film structure.

The lower wiring barrier film 110a may extend along sidewalls and bottom surface of the first lower wiring trench 110t. The lower wiring barrier film 110a may also extend along the sidewalls and bottom surface of second lower wiring trench 120t. The lower wiring fill film 110b may fill the rest of the first and second lower wiring trenches 110t and 120t. In one or more examples, the lower wiring barrier film 110a may be first deposited in the lower wiring trench 110t, and the lower wiring fill film 110b may be subsequently deposited to fill the rest of the trench.

In one or more examples, the lower wiring barrier film 110a may extend along sidewalls and bottom surface of the lower wiring fill film 110b. In one or more examples, the lower wiring barrier film 110a may not be disposed on the sidewalls of the lower wiring fill film 110b. As another example, the lower wiring barrier film 110a may not be disposed on the bottom surface of the lower wiring fill film 110b.

The lower wiring barrier film 110a may include at least one of a metal, a conductive metal nitride, a conductive metal carbide, a conductive metal oxide, a conductive metal carbonitride, and a two-dimensional (2D) material. For example, the lower wiring barrier film 110a may include tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), molybdenum (Mo), and a 2D material. However, as understood by one of ordinary skill in the art, the embodiments of the present disclosure are not limited to these materials and may include any suitable material known to one of ordinary skill in the art.

The 2D material may include a 2D allotrope or compound, for example, at least one of graphene, boron nitride (BN), molybdenum sulfide, molybdenum selenide, tungsten sulfide, tungsten selenide, and tantalum sulfide, but the present disclosure is not limited thereto. For example, the aforementioned 2D materials are listed by way of example, and thus, the present disclosure is not limited thereto.

In one or more examples, the lower wiring fill film 110b may include a metal or a conductive compound containing a metal. The lower wiring fill film 110b may include, for example, at least one of aluminum (Al), copper (Cu), W, Co, Ru, silver (Ag), gold (Au), manganese (Mn), Mo, Rh, Ir, RuAl, NiAl, NbB₂, MoB₂, TaB₂, V₂AlC, CrAlC, but the present disclosure is not limited thereto. If the lower wiring fill film 110b includes Cu, the lower wiring fill film 110b may further include, for example, C, Ag, Co, Ta, indium (In), tin (Sn), zinc (Zn), Mn, Ti, magnesium (Mg), chromium (Cr), germanium (Ge), strontium (Sr), platinum (Pt), Mg, Al, or Zr.

A width, in the first direction, of the first and second lower connection wirings 110 and 120 may decrease as the first and second lower connection wirings 110 and 120 extend away from the upper surface of the first interlayer insulating film 130. In one or more examples, the width, in the first direction, of the first and second lower connection wirings 110 and 120 may increase as the first and second lower connection wirings 110 and 120 extend away from the upper surface of the first interlayer insulating film 130.

Although not illustrated, a via pattern that connects the first lower connection wiring 110 and a conductive pattern below the first lower connection wiring 110 may be further disposed. Similarly, a via pattern that connects the second lower connection wiring 120 and a conductive pattern below the second lower connection wiring 120 may be further disposed.

In one or more examples, each of the first and second lower connection wirings 110 and may have a single conductive film structure.

A second interlayer insulating film 230 may be disposed on the first lower connection wiring 110, the second lower connection wiring 120, and the first interlayer insulating film 130. The second interlayer insulating film 230 may include, for example, at least one of silicon oxide, silicon nitride, silicon oxynitride, and a low-k material.

A first upper etch stop film 140 may be disposed between the first and second interlayer insulating films 130 and 230. The first upper etch stop film 140 may be disposed on the first lower connection wiring 110, the second lower connection wiring 120, and the first interlayer insulating film 130.

The first upper etch stop film 140 may include a material that has an etch selectivity to the second interlayer insulating film 230. For example, the first upper etch stop film 140 may include, for example, at least one of silicon nitride (SiN), silicon oxynitride (SiON), silicon carbonitride (SiOCN), silicon boron nitride (SiBN), silicon boron oxynitride (SiOBN), silicon carbonitride (SiCN), aluminum oxide (AlO), aluminum nitride (AlN), aluminum oxycarbide (AlOC), and a combination thereof. The first upper etch stop film 140 is illustrated as being a single film. However, as understood by one of ordinary skill in the art, the present disclosure is not limited these materials or configurations.

The second interlayer insulating film 230 may include a first upper wiring trench 210t, a first connection via hole 150t, and a second connection via hole 155t. The first upper wiring trench 210t may be disposed within the second interlayer insulating film 230.

The first connection via hole 150t may be formed at the bottom surface of the first upper wiring trench 210t. The first connection via hole 150t may be disposed within the second interlayer insulating film 230 and the first upper etch stop film 140. The first connection via hole 150t may expose the first lower connection wiring 110 through the first upper etch stop film 140.

The second connection via hole 155t may be formed at the bottom surface of the first upper wiring trench 210t. The second connection via hole 155t may be disposed within the second interlayer insulating film 230 and the first upper etch stop film 140. The second connection via hole 155t may expose the second lower connection wiring 120 through the first upper etch stop film 140.

The first connection via 150 may be disposed within the second interlayer insulating film 230 and the first upper etch stop film 140. The first connection via 150 may be connected to the first lower connection wiring 110 through the first upper etch stop film 140. The first connection via 150 may fill the first connection via hole 150t.

The second connection via 155 may be disposed within the second interlayer insulating film 230 and the first upper etch stop film 140. The second connection via 155 may be connected to the second lower connection wiring 120 through the first upper etch stop film 140. The second connection via 155 may fill the second connection via hole 155t.

The first upper connection wiring 210 may be disposed on the first and second lower connection wirings 110 and 120. The first upper connection wiring 210 may be disposed within the second interlayer insulating film 230. The first upper connection wiring 210 may fill the first upper wiring trench 210t.

The planar shape of the first upper connection wiring 210 will be described later.

In one or more examples, the first upper connection wiring 210 may be disposed at a second metal level, which is different from the first metal level. The first upper connection wiring 210 may be disposed at the second metal level higher than the first metal level.

The first upper connection wiring 210 may be disposed on the first connection via 150 and the second connection via 155. The first upper connection wiring 210 may be connected to the first and second connection vias 150 and 155.

The first upper connection wiring 210 may be connected to the first lower connection wiring 110 through the first connection via 150. The first connection via 150 may connect the first upper and lower connection wirings 210 and 110.

The first upper connection wiring 210 may be connected to the second lower connection wiring 120 through the second connection via 155. The second connection via 155 may connect the first upper connection wiring 210 and the second lower connection wiring 120.

The first upper connection wiring 210 may connect the first and second lower connection wirings 110 and 120, which are disposed below the first upper connection wiring 210. For example, the first upper connection wiring 210 may be a bridge wiring that connects the first and second lower connection wirings 110 and 120. In one or more examples, the first and second lower connection wirings 110 and 120 may be provided on a same planar surface as the connection wiring 210 serving as the bridge wiring. In one or more examples, the first and second wirings 110 and 120 may be provided above the connection 210 serving as the bridge wiring.

In one or more examples, each of the first upper connection wiring 210, the first connection via 150, and the second connection via 155 may include an upper wiring barrier film 210a and an upper wiring fill film 210b.

The upper wiring barrier film 210a may extend along sidewalls and bottom surface of the first upper wiring trench 210t, sidewalls and bottom surface of the first connection via hole 150t, and sidewalls and bottom surface of the second connection via hole 155t. The upper wiring fill film 210b may be disposed on the upper wiring barrier film 210a.

For example, the first upper connection wiring 210, the first connection via 150, and the second connection via 155 may be formed at the same level. In one or more examples, the term “the same level” means that the first upper connection wiring 210, the first connection via 150, and the second connection via 155 are formed by the same manufacturing process. In one or more examples, the term “the same level” may also mean that one or more components are formed by the same manufacturing process in a same layer of a semiconductor device.

In one or more examples, the upper wiring fill film 210b of the first upper connection wiring 210 may be separated from the upper wiring fill film 210b of the first connection via 150 by a wiring barrier film. Additionally, the upper wiring fill film 210b of the first upper connection wiring 210 may be separated from the upper wiring fill film 210b of the second connection via 155 by a wiring barrier film. In this case, the first upper connection wiring 210 may be formed by a different manufacturing process from the first and second connection vias 150 and 155. Even if the first upper connection wiring 210 is formed by a different manufacturing process, the first and second connection vias 150 and 155 may be formed by the same manufacturing process.

In one or more examples, the materials included in the upper wiring barrier film 210a and the upper wiring fill film 210b may be substantially the same as the materials included in the lower wiring barrier film 110a and the lower wiring fill film 110b. In one or more examples, the first upper connection wiring 210, the first connection via 150, and the second connection via 155 may have a single-film structure.

As illustrated in FIG. 1, the first upper connection wiring 210 may include a first line portion 210LP1, a second line portion 210LP2, and a first protruding portion 210PP1.

In one or more examples, the first line portion 210LP1 may extend in the second direction. The first line portion 210LP1 may include first and second sidewalls 210LP1_S1 and 210LP1_S2, which are opposite to each other in the first direction. From a planar perspective, the first and second sidewalls 210LP1_S1 and 210LP1_S2 are illustrated as being straight lines. However, as understood by one of ordinary skill in the art, the first and second sidewalls 210LP1_S1 and 210LP1_S2 may be substantially straight or may intersect.

In one or more examples, the second line portion 210LP2 may extend in the first direction. The second line portion 210LP2 may protrude from the first sidewall 210LP1_S1 of the first line portion 210LP1 in the first direction. The second line portion 210LP2 may be directly connected to the first line portion 210LP1. In one or more examples, the second line portion 210LP2 may be indirectly connected to the first line portion 210LP1 via one or more intervening components. In one or more examples, the first line portion 210LP1 and the second line portion 210LP2 may be integrally formed as one piece. In one or more examples, the first line portion 210LP1 and the second line portion 210LP2 may be separate components joined together by one or more known bonding or fusing processes.

In one or more examples, the first protruding portion 210PP1 may protrude from the second sidewall 210LP1_S2 of the first line portion 210LP1 in the first direction. The first protruding portion 210PP1 may be directly connected to the first line portion 210LP1. The first protruding portion 210PP1 and the second line portion 210LP2 may be aligned in the first direction. In one or more examples, the first protruding portion 210PP1 and the second line portion 210LP2 may be integrally formed as one piece. In one or more examples, the first protruding portion 210PP1 and the second line portion 210LP2 may be separate pieces joined together by one or more known bonding or fusing processes.

In one or more examples, the length, in the first direction, of the first protruding portion 210PP1 is less than the length, in the first direction, of the first line portion 210LP1.

At the point where the first and second line portions 210LP1 and 210LP2 are connected, a part of the first sidewall 210LP1_S1 of the first line portion 210LP1 may be illustrated as being rounded. However, as understood by one of ordinary skill in the art, the present disclosure is not limited to these configurations. At the point where the first line portion 210LP1 and the first protruding portion 210PP1 are connected, the second sidewall 210LP1_S2 of the first line portion 210LP1 is illustrated as not being rounded. However, as understood by one of ordinary skill in the art, the present disclosure is not limited to these configurations.

In one or more examples, the first line portion 210LP1 may be connected to the first lower connection wiring 110. The first connection via 150 connects the first line portion 210LP1 and the first lower connection wiring 110. The point where the first upper and lower connection wirings 210 and 110 are connected may be the first line portion 210LP1.

The first connection via 150 may be directly or indirectly connected to the first line portion 210LP1. The first connection via 150 may be disposed below the first line portion 210LP1. The first connection via 150 may overlap with the first line portion 210LP1 in the third direction.

In one or more examples, the second line portion 210LP2 may be connected to the second lower connection wiring 120. The second connection via 155 may connect the second line portion 210LP2 and the second lower connection wiring 120. The point where the second upper connection wiring 210 and the second lower connection wiring 120 are connected may be the second line portion 210LP2.

In one or more examples, the second connection via 155 may be directly or indirectly connected to the second line portion 210LP2. The second connection via 155 may be disposed below the second line portion 210LP2. The second connection via 155 may overlap with the second line portion 210LP2 in the third direction.

In one or more examples, no connection via is disposed below the first protruding portion 210PP1. The first protruding portion 210PP1 is not connected to the connection via disposed within the second interlayer insulating film 230. The first protruding portion 210PP1 does not overlap, in the third direction, with the connection via disposed within the second interlayer insulating film 230.

In one or more examples, the first protruding portion 210PP1 is not directly connected to the connection via. The first upper connection wiring 210 is not connected to the lower connection wiring disposed at the first metal level, through the first protruding portion 210PP1.

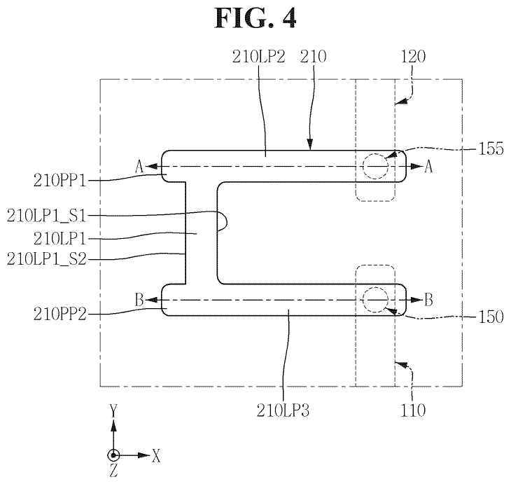

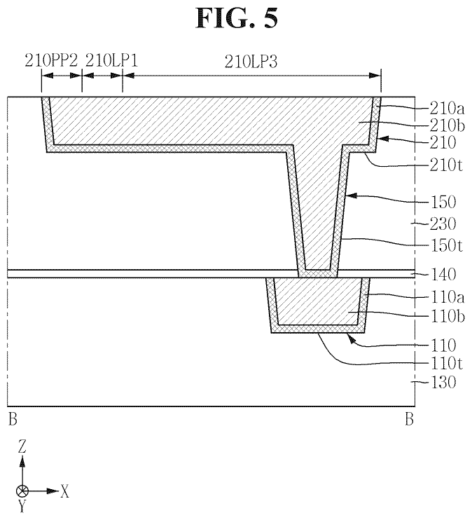

FIGS. 4 and 5 are a plan view and a cross-sectional view, respectively, for explaining a semiconductor device according to some embodiments. For convenience, the semiconductor device of FIGS. 4 and 5 will hereinafter be described, focusing mainly on the differences from the semiconductor device of FIGS. 1 to 3.

Referring to FIGS. 4 and 5, in one or more examples, the first upper connection wiring 210 may further include a third line portion 210LP3, which protrudes in the first direction from the first sidewall 210LP1_S1 of the first line portion 210LP1, and a second protruding portion 210PP2, which protrudes in the first direction from the second sidewall 210LP1_S2 of the first line portion 210LP1.

The third line portion 210LP3 may extend in the first direction. The third line portion 210LP3 may be directly connected to the first line portion 210LP1. In one or more examples, the third line portion 210LP3 may be indirectly connected to the first line portion 210LP1 via one or more intervening components. In one or more examples, the first line portion 210LP1 and the third line portion 210LP3 may be integrally formed as one piece. In one or more examples, the first line portion 210LP1 and the third line portion 210LP3 may be separate components joined together by one or more known bonding or fusing processes.

The third line portion 210LP3 may overlap with the second line portion 210LP2 in the second direction. The third line portion 210LP3 may be spaced apart from the second line portion 210LP2 in the second direction.

In one or more examples, the second protruding portion 210PP2 may be directly connected to the first line portion 210LP1. The second protruding portion 210PP2 and the third line portion 210LP3 may be aligned in the first direction. In one or more examples, thee length, in the first direction, of the second protruding portion 210PP2 is less than the length, in the first direction, of the third line portion 210LP3. In one or more examples, the second protruding portion 210PP2 and the third line portion 210LP3 may be integrally formed as one piece. In one or more examples, the second protruding portion 210PP2 and the third line portion 210LP3 may be separate pieces joined together by one or more known bonding or fusing processes.

In one or more examples, the third line portion 210LP3 may be connected to a first lower connection wiring 110. The first connection via 150 connects the third line portion 210LP3 and the first lower connection wiring 110. The point where the first upper connection wiring 210 and the first lower connection wiring 110 are connected may be the third line portion 210LP3.

In one or more examples, the first connection via 150 may be directly connected to the third line portion 210LP3. The first connection via 150 may be disposed below the third line portion 210LP3. The first connection via 150 may overlap with the third line portion 210LP3 in the third direction.

In one or more examples, no connection via may be disposed below the first line portion 210LP1. The first line portion 210LP1 may not be directly connected to the connection via disposed within the second interlayer insulating film 230. The first upper connection wiring 210 may not be connected to the lower connection wiring disposed at a first metal level, through the first line portion 210LP1.

In one or more examples, no connection via is disposed below the second protruding portion 210PP2. The second protruding portion 210PP2 is not connected to the connection via disposed within the second interlayer insulating film 230. The second protruding portion 210PP2 does not overlap with the connection via disposed within the second interlayer insulating film 230 in the third direction.

In one or more examples, the second protruding portion 210PP2 is not directly connected to the connection via. The first upper connection wiring 210 is not connected to the lower connection wiring disposed at the first metal level, through the second protruding portion 210PP2.

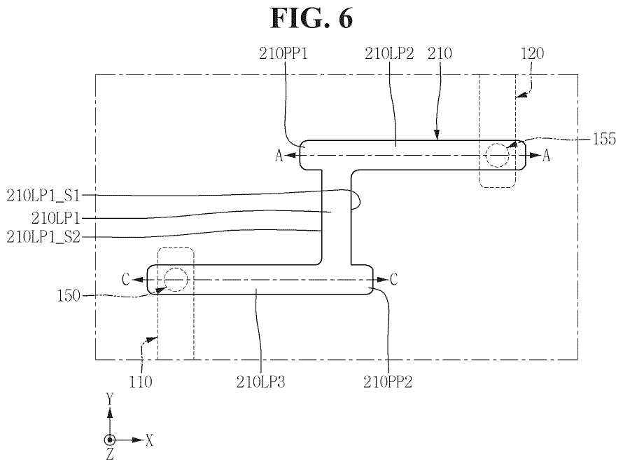

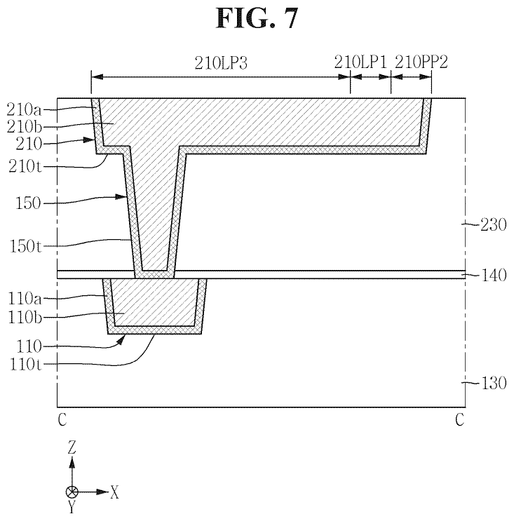

FIGS. 6 and 7 are a plan view and a cross-sectional view, respectively, for explaining a semiconductor device according to some embodiments. For convenience, the semiconductor device of FIGS. 6 and 7 will hereinafter be described, focusing mainly on the differences from the semiconductor device of FIGS. 4 and 5.

Specifically, FIG. 7 is a cross-sectional view taken along line C-C of FIG. 6.

Referring to FIGS. 6 and 7, a third line portion 210LP3 may protrude in a first direction from a second sidewall 210LP1_S2 of a first line portion 210LP1.

The second protruding portion 210PP2 may protrude in the first direction from the first sidewall 210LP1_S1 of the first line portion 210LP1. The second protruding portion 210PP2 and the third line portion 210LP3 may be aligned in the first direction.

In one or more examples, the third line portion 210LP3 does not overlap with a second line portion 210LP2 in the second direction. The third line portion 210LP3 may overlap with the first protruding portion 210PP1 in the second direction. The first line portion 210LP1 may overlap with the second protruding portion 210PP2 in the second direction.

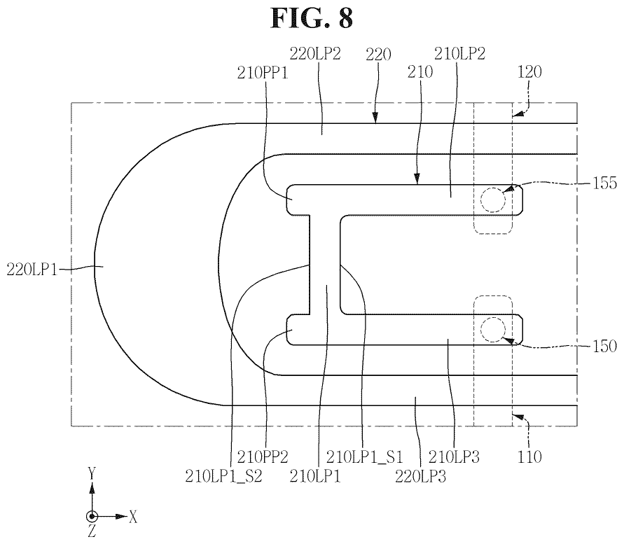

FIG. 8 is a plan view for explaining a semiconductor device according to some embodiments. For convenience, the semiconductor device of FIG. 8 will hereinafter be described, focusing mainly on the differences from the semiconductor device of FIGS. 4 and 5.

Referring to FIG. 8, the semiconductor device according to some embodiments may further include a second upper connection wiring 220, which is disposed within the second interlayer insulating film (“230” of FIG. 5).

In one or more examples, the second upper connection wiring 220 is disposed at the second metal level higher than the first metal level. The second upper connection wiring 220 may be disposed at the same metal level as the first upper connection wiring 210. In one or more examples, the second upper connection wiring 220 may include the upper wiring barrier film (“210a” of FIG. 5) and the upper wiring fill film (“210b” of FIG. 5), similarly to the first upper connection wiring 210.

The second upper connection wiring 220 may include a fourth line portion 220LP1, a fifth line portion 220LP2, and a sixth line portion 220LP3.

The fourth line portion 220LP1 may extend in the second direction. The fourth line portion 220LP1 may include first and second sidewalls, which are opposite to each other in the first direction. From a planar perspective, the first and second sidewalls of the fourth line portion 220LP1 are illustrated as being curved. However, as understood by one of ordinary skill in the art, the present disclosure is not limited to these configurations.

The fifth line portion 220LP2 may protrude from the fourth line portion 220LP1 in the first direction. The fifth line portion 220LP2 may extend in the first direction. The fifth line portion 220LP2 may be directly connected to the fourth line portion 220LP1. In one or more examples, the fifth line portion 220LP2 may be indirectly connected to the fourth line portion 220LP1 via one or more intervening components. In one or more examples, the fifth line portion 220LP2 and the fourth line portion 220LP1 may be integrally formed as one piece. In one or more examples, the fifth line portion 220LP2 and the fourth line portion 220LP1 may be separate components joined together by one or more known bonding or fusing processes.

The sixth line portion 220LP3 may protrude from the fourth line portion 220LP1 in the first direction. The sixth line portion 220LP3 may extend in the first direction. The sixth line portion 220LP3 may be directly connected to the fourth line portion 220LP1. In one or more examples, the sixth line portion 220LP3 may be indirectly connected to the fourth line portion 220LP1 via one or more intervening components. In one or more examples, the sixth line portion 220LP3 and the fourth line portion 220LP1 may be integrally formed as one piece. In one or more examples, the sixth line portion 220LP3 and the fourth line portion 220LP1 may be separate components joined together by one or more known bonding or fusing processes.

The fifth line portion 220LP2 may overlap with the sixth line portion 220LP3 in the second direction. The fifth line portion 220LP2 may be spaced apart from the sixth line portion 220LP3 in the second direction.

For example, the first upper connection wiring 210 may be disposed between the fifth and sixth line portions 220LP2 and 220LP3.

In one or more examples, the second upper connection wiring 220 does not include the first and second protruding portions 210PP1 and 210PP2 of FIGS. 1 to 7.

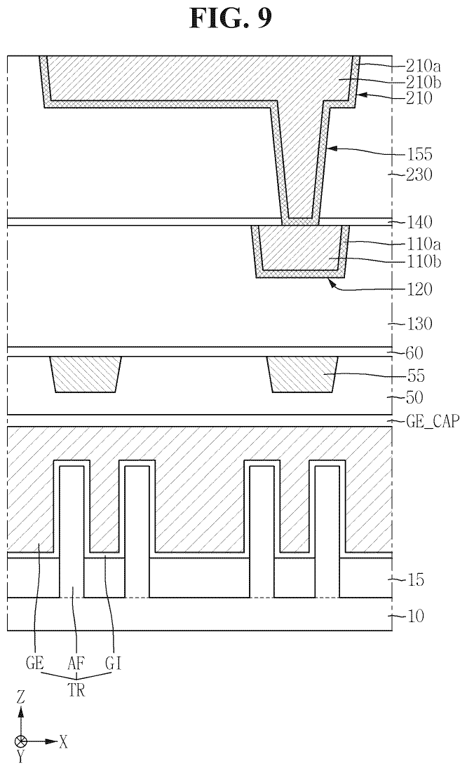

FIG. 9 is a cross-sectional view for explaining a semiconductor device according to some embodiments of the present disclosure. For convenience, the semiconductor device of FIG. 9 will hereinafter be described, focusing mainly on the differences from the semiconductor device of FIGS. 1 to 3.

Specifically, FIG. 9 is a cross-sectional view taken across a first gate electrode GE.

Referring to FIG. 9, in one or more examples, fin-type patterns AF may extend in the second direction, and the first gate electrode GE may extend in the first direction. However, the present disclosure is not limited to these configurations. In one or more examples, the fin patterns AF may extend in the first direction, and the first gate electrode GE may extend in the second direction.

The semiconductor device, according to some embodiments of the present disclosure, may include transistors TR, which are disposed between a substrate 10 and the first lower connection wiring 110.

The substrate 10 may be a silicon (Si) substrate or a silicon-on-insulator (SOI). In one or more examples, the substrate 10 may include silicon germanium (SiGe), a silicon germanium-on-insulator (SGOI), indium antimonide, a lead tellurium compound, indium arsenide, indium phosphide, gallium arsenide, or gallium antimonide, or any other suitable material known to one of ordinary skill in the art.

The transistors TR may include the fin-type patterns AF, the first gate electrode GE, which is on the fin-type patterns AF, and a first gate insulating film GI, which is disposed between the first gate electrode GE and the fin-type patterns AF.

In one or more examples, the transistors TR may include source/drain patterns disposed on both sides of the first gate electrode GE.

The fin-type patterns AF may protrude from the substrate 10. The fin-type patterns AF may extend in the second direction. The fin-type patterns AF may be parts of the substrate 10 or may include an epitaxial layer grown from the substrate 10. The fin-type patterns AF may include, for example, an element semiconductor material such as Si or Ge. In one or more examples, the fin-type patterns AF may include a compound semiconductor such as, for example, a group IV-IV compound semiconductor or a group III-V compound semiconductor.

The group IV-IV compound semiconductor may be a binary or ternary compound including at least two of C, Si, Ge, and Sn or a compound obtained by doping the binary or ternary compound with a group IV element. The group III-V compound semiconductor may be a binary, ternary, or quaternary compound obtained by combining at least one group III element such as Al, Ga, or In and a group V element such as phosphorus (P), arsenic (As), or antimony (Sb).

In one or more examples, a field insulating film 15 may be disposed on the substrate 10. The field insulating film 15 may be formed on parts of the sidewalls of each of the fin-type patterns AF. The fin-type patterns AF may protrude beyond the upper surface of the field insulating film 15. The field insulating film 15 may include, for example, an oxide film, a nitride film, an oxynitride film, or a combination thereof.

In one or more examples, the first gate electrode GE may be disposed on the fin-type patterns AF. The first gate electrode GE may extend in the first direction. The first gate electrode GE may intersect the fin-type patterns AF.

In one or more examples, the first gate electrode GE may include at least one of, for example, a metal, a conductive metal nitride, a conductive metal carbonitride, a conductive metal carbide, a metal silicide, a doped semiconductor material, a conductive metal oxynitride, and a conductive metal oxide.

In one or more examples, the first gate insulating film GI may be disposed between the first gate electrode GE and the fin-type patterns AF and between the first gate electrode GE and the field insulating film 15. The first gate insulating film GI may include, for example, silicon oxide, silicon oxynitride, silicon nitride, or a high-k material having a greater dielectric constant than silicon oxide. The high-k material may include at least one of, for example, boron nitride, a metal oxide, and a metal silicon oxide.

The semiconductor device, according to some embodiments of the present disclosure, may include negative capacitance (NC) FETs using negative capacitors. For example, the first gate insulating film GI may include a ferroelectric material film having ferroelectric properties and a paraelectric material film having paraelectric properties. As understood by one of ordinary skill in the art, negative capacitance may occur when an increase in charge leads to a decrease in voltage.

In one or more examples, the ferroelectric material film may have negative capacitance, and the paraelectric material film may have positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having negative capacitance and the paraelectric material film having positive capacitance are connected in series, the total capacitance of the ferroelectric material film and the paraelectric material film may increase. Accordingly, a transistor having the ferroelectric material film can have a sub-threshold swing (SS) of less than 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), silicon, calcium (Ca), cerium (Ce), dysprosium (Dy), erbium (Er), gadolinium (Gd), germanium, scandium (Sc), strontium (Sr), and Sn. The type of dopant may vary depending on the type of material of the ferroelectric material film.

If the ferroelectric material film includes hafnium oxide, the dopant of the ferroelectric material film may include, for example, at least one of Gd, Si, Zr, Al, and Y.

If the dopant of the ferroelectric material film is Al, the ferroelectric material film may include 3 atomic % (at %) to 8 at % of Al. As understood by one of ordinary skill in a weight percentage (wt %) of an element may be the weight of that element measured in the sample divided by the weight of all elements in the sample multiplied by 100. The at % may be the number of atoms of that element, at that weight percentage, divided by the total number of atoms in the sample multiplied by 100. In one or more examples, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include 2 at % to 10 at % of Si. If the dopant of the ferroelectric material film is Y, the ferroelectric material film may include 2 at % to 10 at % of Y. If the dopant of the ferroelectric material film is Gd, the ferroelectric material film may include 1 at % to 7 at % of Gd. If the dopant of the ferroelectric material film is Zr, the ferroelectric material film may include 50 at % to 80 at % of Zr.

In one or more examples, the paraelectric material film may include paraelectric properties. The paraelectric material film may include, for example, at least one of silicon oxide and a high-k metal oxide. The high-k metal oxide may include, for example, at least one of hafnium oxide, zirconium oxide, and aluminum oxide, but the present disclosure is not limited thereto.

In one or more examples, the ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, 0.5 nm to 10 nm, but the present disclosure is not limited thereto. A critical thickness that can exhibit ferroelectric properties may vary depending on the type of ferroelectric material, and thus, the thickness of the ferroelectric material film may vary depending on the type of ferroelectric material included in the ferroelectric material film.

For example, the first gate insulating film GI may include one ferroelectric material film. In another example, the first gate insulating film GI may include a plurality of ferroelectric material films that are spaced apart from one another. The first gate insulating film GI may have a structure in which a plurality of ferroelectric material films and a plurality of paraelectric material films are alternately stacked.

In one or more examples, a gate capping pattern GE_CAP may be disposed on the first gate electrode GE. The second lower connection wiring 120 may be disposed on the first gate electrode GE. The second lower connection wiring 120 is illustrated as not being connected to the first gate electrode GE, but the present disclosure is not limited thereto.

In one or more examples, a lower wiring 55 may be disposed between the gate capping pattern GE_CAP and the second lower connection wiring 120. The lower wiring 55 may be disposed within a third interlayer insulating film 50.

In one or more examples, the third interlayer insulating film 50 may be disposed between the gate capping pattern GE_CAP and the first interlayer insulating film 130. The third interlayer insulating film 50 may include, for example, at least one of silicon oxide, silicon nitride, silicon oxynitride, and a low-k material.

The lower wiring 55 is illustrated as extending in the second direction, but the present disclosure is not limited these configurations. In one or more examples, the lower wiring 55 may extend in the first direction.

The lower wiring 55 may include, for example, at least one of a metal, a conductive metal nitride, a conductive metal carbonitride, a conductive metal carbide, a conductive metal oxynitride, a conductive metal oxide, and a 2D material. The lower wiring 55 is illustrated as being a single film, but the present disclosure is not limited thereto. In one or more examples, the lower wiring 55, like the second lower connection wiring 120, may include a wiring barrier layer and a wiring fill layer.

In one or more examples, a second upper etch stop film 60 may be disposed between the third interlayer insulating film 50 and the first interlayer insulating film 130. The second upper etch stop film 60 may extend along the upper surface of the third interlayer insulating film 50 and the upper surface of the lower wiring 55. The first interlayer insulating film 130 may be disposed on the second upper etch stop film 60.

The second upper etch stop film 60 may include, for example, at least one of silicon nitride, silicon oxynitride, silicon carbonitride, silicon carbide, silicon oxycarbide, silicon boron nitride, silicon boron oxynitride, aluminum oxide, aluminum nitride, aluminum oxycarbide, and a combination thereof. The second upper etch stop film 60 is illustrated as being a single film, but the present disclosure is not limited this structure, and may include any suitable film structure known to one of ordinary skill in the art.

In one or more examples, an additional lower wiring may be further disposed between the lower wiring 55 and the first gate electrode GE. As another example, additional lower connection wiring may be further disposed between the lower wiring 55 and the second lower connection wiring 120.

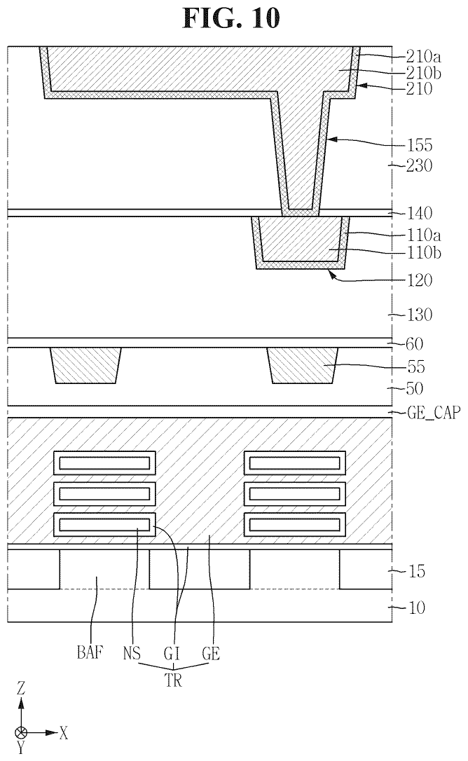

FIG. 10 is a cross-sectional view for explaining a semiconductor device according to some embodiments of the present disclosure. For convenience, the semiconductor device of FIG. 10 will hereinafter be described, focusing mainly on the differences from the semiconductor device of FIG. 9.

Referring to FIG. 10, in one or more examples, transistors TR may include nanosheets NS, a first gate electrode GE, which surrounds the nanosheets NS, and first gate insulating films GI, which are between the first gate electrode GE and the nanosheets NS.

The nanosheets NS may be disposed on lower fin-type patterns BAF. The nanosheets NS may be spaced apart from the lower fin-type patterns BAF in a third direction. Each of the transistors TR is illustrated as including three nanosheets NS, which are spaced apart from one another in the third direction, but the present disclosure is not limited thereto. In one or more examples, more than three nanosheets NS, or less than three nanosheets NS, may be disposed on each of the lower fin-type patterns BAF in the third direction.

The lower fin-type patterns BAF and the nanosheets NS may include an element semiconductor material such as, for example, Si or Ge. The lower fin-type patterns NS and the nanosheets NS may include a compound semiconductor such as, for example, a group IV-IV compound semiconductor or a group III-V compound semiconductor. The lower fin-type patterns BAF and the nanosheets NS may include the same material or may include different materials.

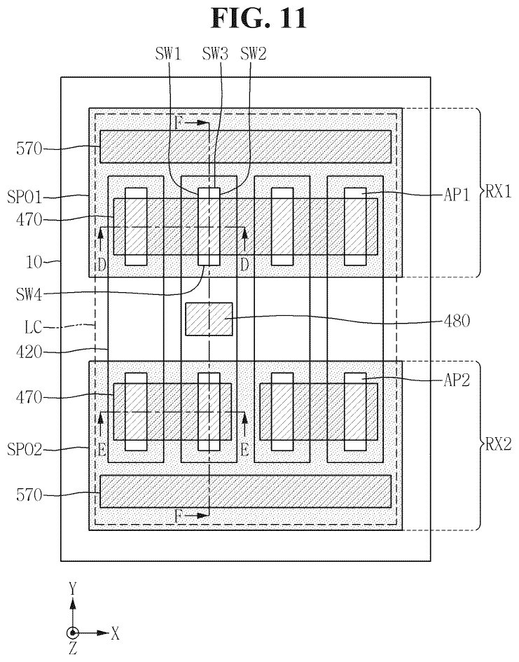

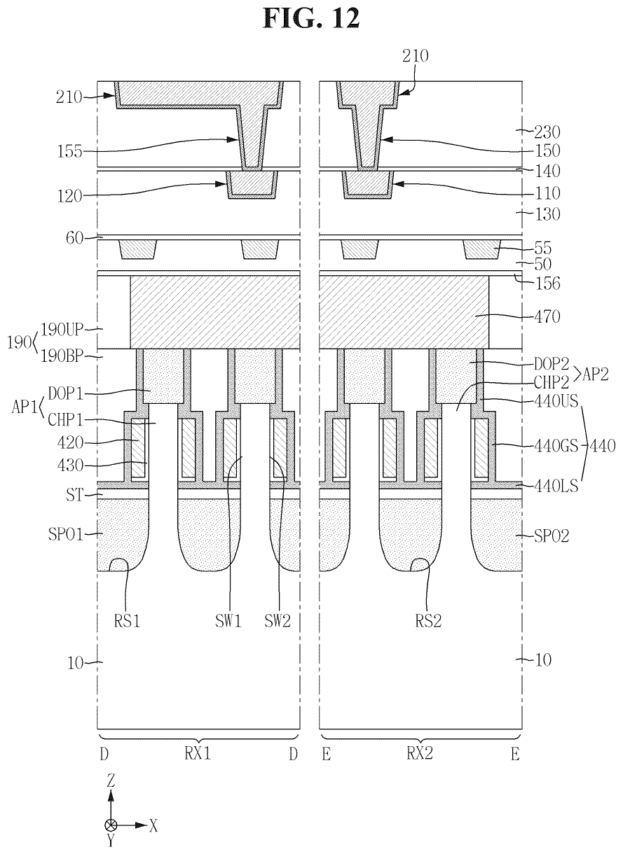

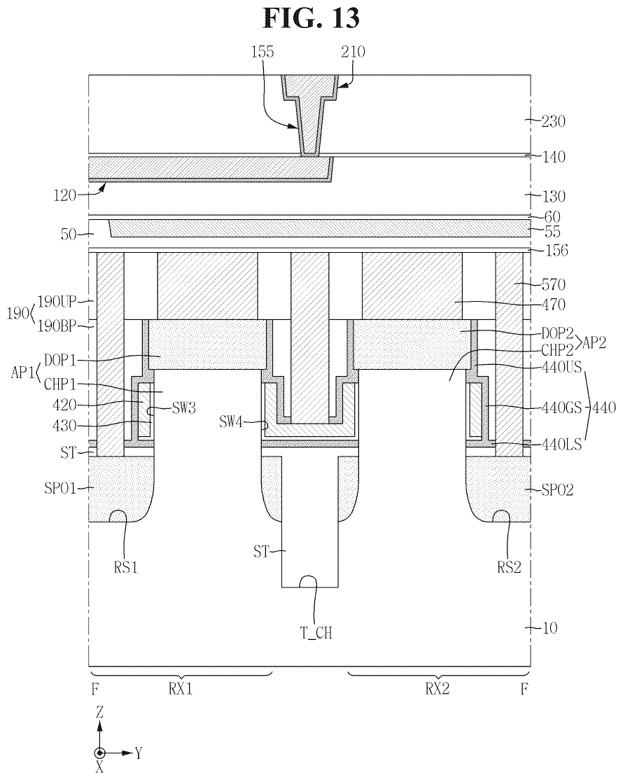

FIGS. 11 to 13 illustrate a semiconductor device according to some embodiments of the present disclosure. Specifically, FIG. 11 is a plan view for explaining a semiconductor device according to some embodiments of the present disclosure. FIG. 12 is a cross-sectional view taken along line D-D and line E-E of FIG. 11. and FIG. 13 is a cross-sectional view taken along line F-F of FIG. 11.

Referring to FIGS. 11 to 13, in one or more examples, a logic cell LC may be provided on a substrate 10. The logic cell LC may be a logic element (e.g., an inverter, a flipflop, or the like) performing a particular function. The logic cell LC may include VFETs, which form a logic element, and wires, which connect the VFETs.

The logic cell LC on the substrate 10 may include first and second active regions RX1 and RX2. For example, the first active region RX1 may be a P-type metal-oxide semiconductor (MOSFET) region, and the second active region RX2 may be an N-type MOSFET region. The first and second active regions RX1 and RX2 may be defined by a trench T_CH, which is formed in the substrate 10. The first and second active regions RX1 and RX2 may be spaced apart from each other in the second direction. As understood by one of ordinary skill in the art, region RX1 may be an N-type MOSFET region and RX2 may be an N-type MOSFET region.

A first lower epitaxial pattern SPO1 may be provided in the first active region RX1, and a second lower epitaxial pattern SPO2 may be provided in the second active region RX2. From a planar perspective, the first lower epitaxial pattern SPO1 may overlap with the first active region RX1, and the second lower epitaxial pattern SPO2 may overlap with the second active region RX2. The first and second lower epitaxial patterns SPO1 and SPO2 may be obtained by a selective epitaxial growth process. The first lower epitaxial pattern SPO1 may be provided in a first recess region RS1 of the substrate 10, and the second lower epitaxial pattern SPO2 may be provided in a second recess region RS2 of the substrate 10.

First active patterns AP1 may be provided in the first active region RX1, and second active patterns AP2 may be provided in the second active region RX2. The first active patterns AP1 and the second active patterns AP2 may have a fin shape protruding vertically. From a planar perspective, the first active patterns AP1 and the second active patterns AP2 may have a bar shape extending in the second direction. The first active patterns AP1 may be arranged along the first direction, and the second active patterns AP2 may be arranged along the first direction.

The first active patterns AP1 may include first channel patterns CHP1, which protrude vertically from the first lower epitaxial pattern SPO1, and first upper epitaxial patterns DOP1, which are on the first channel patterns CHP1. The second active patterns AP2 may include second channel patterns CHP2, which protrude vertically from the second lower epitaxial pattern SPO2, and second upper epitaxial patterns DOP2, which are on the second channel patterns CHP2.

In one or more examples, a device isolation film ST may be provided on the substrate 10 to fill the trench T_CH. The device isolation film ST may cover the upper surfaces of the first and second lower epitaxial patterns SPO1 and SPO2. The first active patterns AP1 and the second active patterns AP2 may protrude vertically from the device isolation film ST.

A plurality of second gate electrodes 420, which extend in parallel to one another in the second direction, may be provided on the device isolation film ST. The second gate electrodes 420 may be arranged along the first direction. The second gate electrodes 420 may surround the second channel patterns CHP2 of the second active patterns AP2. For example, each of the first channel patterns CHP1 may include first through fourth sidewalls SW1 through SW4. The first and second sidewalls SW1 and SW2 may be opposite to each other in the first direction, and the third and fourth sidewalls SW3 and SW4 may be opposite to each other in the second direction. The second gate electrodes 420 may be provided on the first through fourth sidewalls SW1 through SW4 of each of the first channel patterns CHP1. In other words, the second gate electrodes 420 may surround the first through fourth sidewalls SW1 through SW4 of each of the first channel patterns CHP1.

In one or more examples, second gate insulating films 430 may be interposed between the second gate electrodes 420 and the first channel patterns CHP1 and between the second gate electrodes 420 and the second channel patterns CHP2. The second gate insulating films 430 may cover the bottom surface and the inner sidewalls of each of the second gate electrodes 420. For example, the second gate insulating films 430 may directly cover the first through fourth sidewalls SW1 through SW4 of each of the first active patterns AP1.

In one or more examples, the first upper epitaxial patterns DOP1 and the second upper epitaxial patterns DOP2 may protrude vertically from the second gate electrodes 420. The upper surfaces of the second gate electrodes 420 may be lower than the bottom surfaces of the first upper epitaxial patterns DOP1 and the bottom surfaces of the second upper epitaxial patterns DOP2. For example, the first active patterns AP1 and the second active patterns AP2 may protrude vertically from the substrate 10 to penetrate the second gate electrodes 420.

The semiconductor device according to some embodiments of the present disclosure may include VFETs where carriers move in the third direction. For example, when the VFETs are on in response to a voltage being applied to the second gate electrodes 420, carriers may move from the first or second lower epitaxial pattern SPO1 or SPO2 to the first or second upper epitaxial patterns DOP1 or DOP2 through the first or second channel patterns CHP1 or CHP2. The second gate electrodes 420 may surround the first through fourth sidewalls of each of the first or second channel patterns CHP1 or CHP2. The VFETs may have a gate-all-around structure. As channels are surrounded by gates, the semiconductor device according to some embodiments of the present disclosure, can have excellent electrical properties.

In one or more examples, a spacer 440, which covers the second gate electrodes 420, the first active patterns AP1, and the second active patterns AP2, may be provided on the device isolation film ST. The spacer 440 may include a silicon nitride film or a silicon oxynitride film. The spacer 440 may include a lower spacer 440LS, an upper spacer 440US, and a gate spacer 440GS between the lower and upper spacers 440LS and 440US.

The lower spacer 440LS may directly cover the upper surface of the device isolation film ST. Due to the lower spacer 440LS, the second gate electrodes 420 may be spaced apart from the device isolation film ST in the third direction. The gate spacer 440GS may cover the upper surface and the outer sidewalls of each of the second gate electrodes 420. The upper spacer 440US may cover the first upper epitaxial patterns DOP1 and the second upper epitaxial patterns DOP2. However, the upper spacer 440US may not cover but expose the upper surfaces of the first upper epitaxial patterns DOP1 and the upper surfaces of the second upper epitaxial patterns DOP2.

A first part 190BP of a lower interlayer insulating film 190 may be provided on the spacer 440. The upper surface of the first part 190BP of the lower interlayer insulating film 190 may form substantially the same plane as the upper surfaces of the first upper epitaxial patterns DOP1 and the upper surfaces of the second upper epitaxial patterns DOP2. A second part 190UP of the lower interlayer insulating film 190, a third interlayer insulating film 50, a first interlayer insulating film 130, and a second interlayer insulating film 230 may be sequentially stacked on the first part 190BP of the lower interlayer insulating film 190. The first and second parts 190BP and 190UP may be included in the lower interlayer insulating film 190. The second part 190UP of the lower interlayer insulating film 190 may cover the upper surfaces of the first upper epitaxial patterns DOP1 and the upper surfaces of the second upper epitaxial patterns DOP2.

One or more first source/drain contacts 470, which are connected to the first upper epitaxial patterns DOP1 and the second upper epitaxial patterns DOP2 through the second part 190UP of the lower interlayer insulating film 190, may be provided. One or more second source/drain contacts 570, which are connected to the first and second lower epitaxial patterns SPO1 and SPO2 sequentially through the lower interlayer insulating film 190, the lower spacer 440LS, and the device isolation film ST, may be provided. A gate contact 480, which is connected to the second gate electrodes 420 sequentially through the second part 190UP of the lower interlayer insulating film 190, the first part 190BP of the lower interlayer insulating film 190, and the gate spacer 440GS, may be provided.

A lower etch stop film 156 may be additionally disposed between the second part 190UP of the lower interlayer insulating film 190 and the third interlayer insulating film 50. A second etch stop film 60 may be disposed between the third interlayer insulating film 50 and the first interlayer insulating film 130.

The lower wiring 55 may be provided within the third interlayer insulating film 50. The first and second lower connection wirings 110 and 120 may be provided within the first interlayer insulating film 130. The first upper connection wiring 210, which connects the first and second lower connection wirings 110 and 120, may be disposed on the first and second lower connection wirings 110 and 120.

The detailed description of the first upper connection wire 210 may be substantially the same as that previously described using FIGS. 1 to 8.

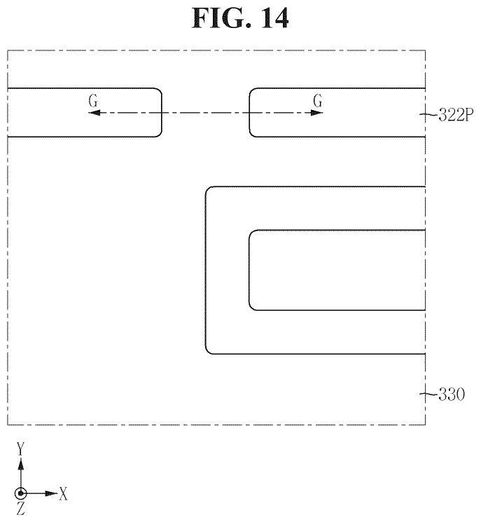

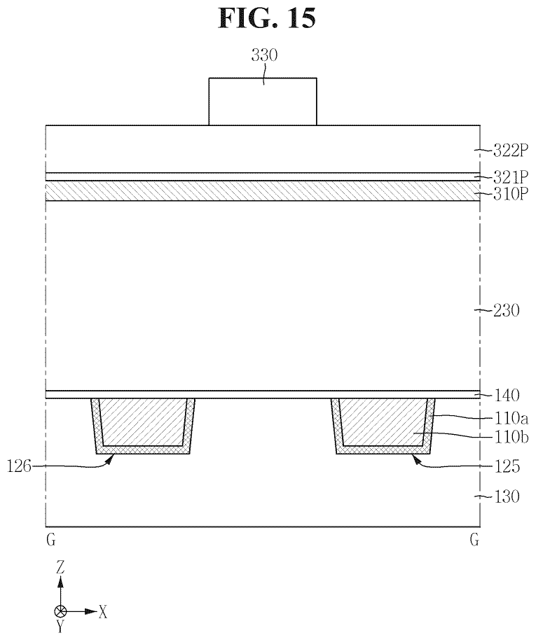

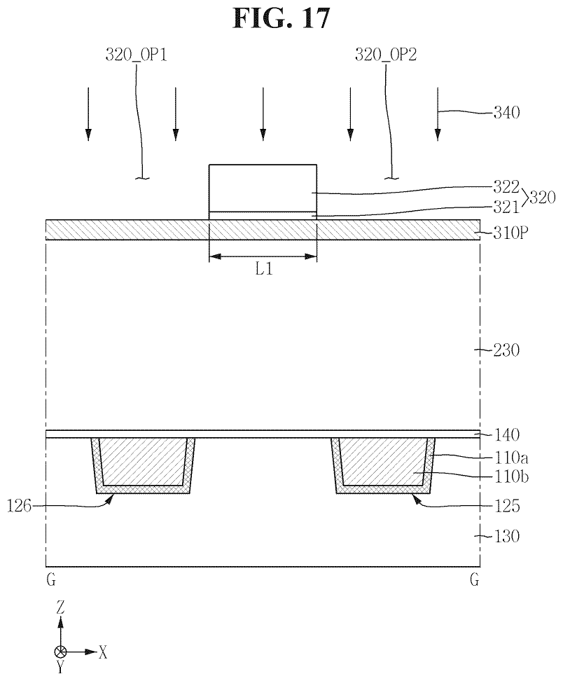

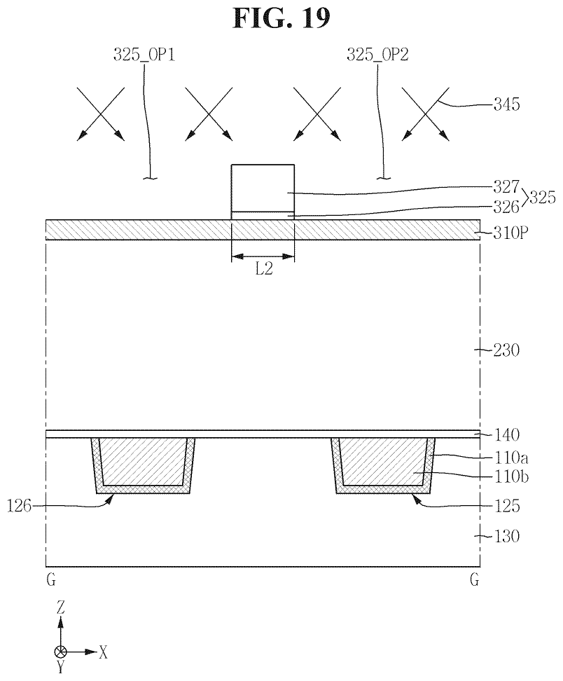

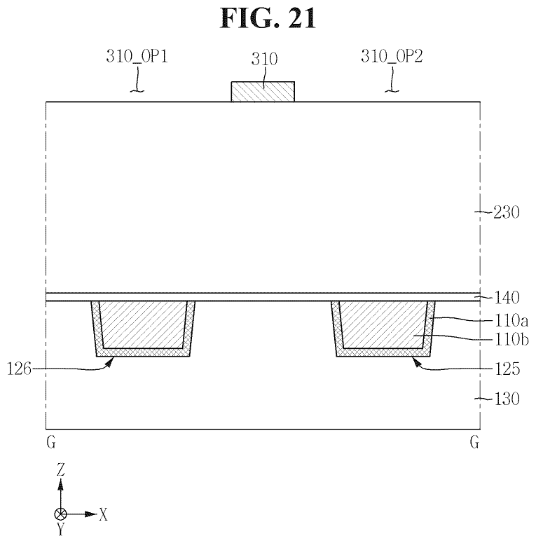

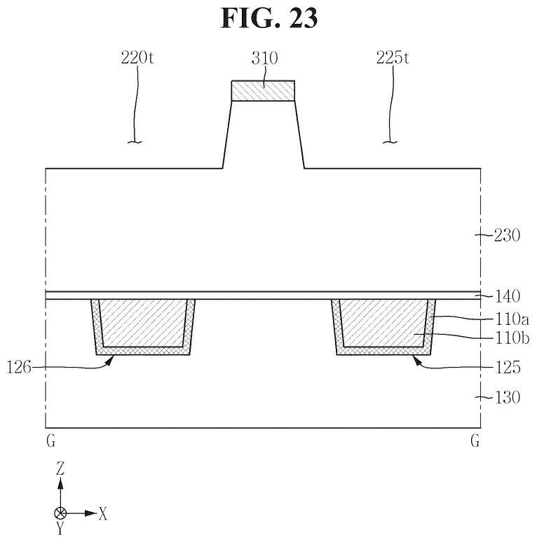

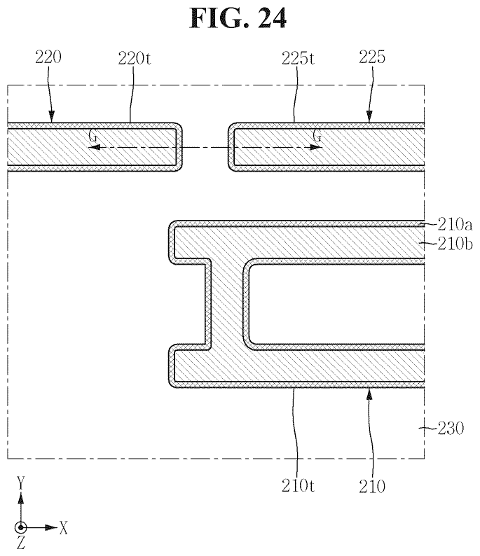

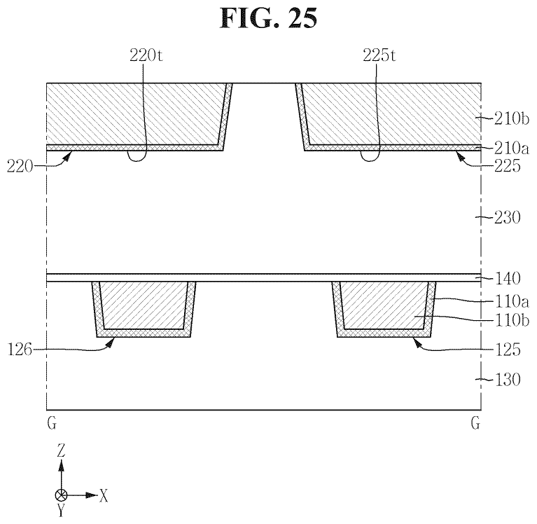

FIGS. 14 to 25 are schematic diagrams for explaining intermediate steps of a method of manufacturing a semiconductor device, according to some embodiments. Specifically, FIGS. 15, 17, 19, 21, 23, and 25 are cross-sectional views taken along lines G-G of FIGS. 14, 16, 18, 20, 22, and 24, respectively. The method of manufacturing illustrated in FIGS. 14-25 may be used to form any one of the semiconductor devices illustrated in FIGS. 1-13.

Referring to FIGS. 14 and 15, a third lower connection wiring 125 and a fourth lower connection wiring 126 may be formed within the first interlayer insulating film 130.

In one or more examples, the first interlayer insulating film 130 may be formed on a substrate (“10” of FIGS. 9 to 13).

The third and fourth lower connection wirings 125 and 126 may extend, for example, in the second direction. The third and fourth lower connection wirings 125 and 126 may include a lower wiring barrier film 110a and a lower wiring fill film 110b. The descriptions of the third and fourth lower connection wirings 125 and 126 may be substantially the same as those of the first and second lower connection wirings 110 and 120 of FIGS. 1 and 2.

The first upper etch stop film 140 may be sequentially formed on the first interlayer insulating film 130, the third lower connection wiring 125, and the fourth lower connection wiring 126. The second interlayer insulating film 230 may be formed on the first upper etch stop film 140.

Thereafter, a hard mask film 310P, a lower mask film 321P, and an upper mask film 322P may be sequentially formed on the second interlayer insulating film 230.

The hard mask film 310P may include a conductive material. For example, the hard mask film 310P may contain titanium nitride (TiN), but the present disclosure is not limited these materials. The hard mask film 310P may be formed by physical vapor deposition (PVD), atomic layer deposition (ALD), or chemical vapor deposition (CVD), but the present disclosure is not limited to these materials.

The lower mask film 321P and the upper mask film 322P may include, for example, at least one of a silicon-based material such as silicon oxide, silicon oxynitride, silicon nitride, TEOS, or polycrystalline silicon and a carbon-based material such as an amorphous carbon layer (ACL) or Spin-On Hardmask (SOH).

For example, the lower mask film 321P may include, but is not limited to, silicon oxynitride, and the upper mask film 322P may include, but is not limited to, SOH. The lower mask film 321P and the upper mask film 322P may be formed by ALD, CVD, or spin coating, but the present disclosure is not limited thereto.

Two mask films are illustrated as being formed on the hard mask film 310P, but the present disclosure is not limited to these configurations. In one or more examples, an additional mask film may be further formed on the upper mask film 322P. The additional mask film may include, for example, silicon oxynitride, but the present disclosure is not limited to these configurations.

Thereafter, a photo mask pattern 330 may be formed on the upper mask film 322P. The photo mask pattern 330 is illustrated as exposing part of the upper mask film 322P, but the present disclosure is not limited to these configurations. If an additional mask film is further formed on the upper mask film 322P, the photo mask pattern 330 may expose part of the additional mask film.

Referring to FIGS. 14 to 17, the lower and upper mask films 321P and 322P may be patterned using the photo mask pattern 330 as an etching mask in a first etching process 340, according to some embodiments.

As the lower and upper mask films 321P and 322P are patterned, a first mask pattern 320 may be formed. The first mask pattern 320 may be formed on the hard mask film 310P.

The first mask pattern 320 may include a first opening 320_OP1, a second opening 320_OP2, and a third opening 320_OP3. The first, second, and third openings 320_OP1, 320_OP2, and 320_OP3 may expose the hard mask film 310P.

The first and second openings 320_OP1 and 320_OP2 may have a linear shape. The first and second openings 320_OP1 and 320_OP2 may be aligned, for example, in the first direction. The first and second openings 320_OP1 and 320_OP2 may be spaced apart by a first distance L1 in the first direction.

The third opening 320_OP3 may have, for example, an angular U shape. In one or more examples, the third opening 320_OP3 may have an L shape or a shape obtained by combining an L shape and a reverse-L shape.

The first mask pattern 320 may include a first lower mask pattern 321 and a first upper mask pattern 322, which are sequentially formed on the hard mask film 310P. The first lower mask pattern 321 may be formed by patterning the lower mask film 321P. The first upper mask pattern 322 may be formed by patterning the upper mask film 322P.

If an additional mask film is formed on the upper mask film 322P, the additional mask film may be removed during the formation of the first mask pattern 320.

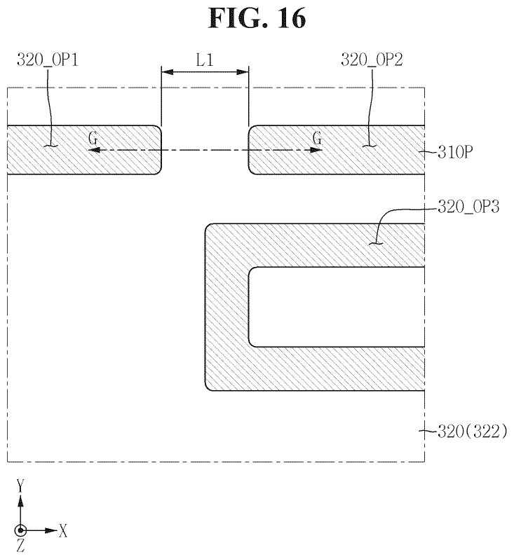

Referring to FIGS. 16 to 19, a second mask pattern 325 may be formed on the hard mask film 310P by etching the first mask pattern 320, according to some embodiments.

The second mask pattern 325 may be formed using a second etching process 345. The second etching process 345 may be the process of etching the first mask pattern 320. The second etching process 345 may include an ion beam etching process that uses an ion beam. The ion beam used in the second etching process 345 may be directed toward the substrate 10 at an oblique angle. Here, the “oblique angle” is an acute angle relative to the third direction.

The second mask pattern 325 may include a fourth opening 325_OP1, a fifth opening 325_OP2, and a sixth opening 325_OP3.

The fourth and fifth openings 325_OP1 and 325_OP2 may have a linear shape. The fourth opening 325_OP1 may be formed by expanding the first opening 320_OP1 of the first mask pattern 320 in the first direction. In one or more examples, the fifth opening 325_OP2 may be formed by expanding the second opening 320_OP2 of the first mask pattern 320 in the first direction.

As the first and second openings 320_OP1 and 320_OP2 of the first mask pattern 320 are expanded by the second etching process 345, a second distance L2, which is the distance, in the first direction, between the fourth and fifth openings 325_OP1 and 325_OP2, is less than the first distance L1, which is the distance, in the first direction, between the first and second openings 320_OP1 and 320_OP2.

The sixth opening 325_OP3 may be formed by expanding the third opening 320_OP3 of the first mask pattern 320 in the first direction. For example, the third opening 320_OP3 of the first mask pattern 320 may include a first portion that extends in the first direction and a second portion that extends in the second direction. As the first portion of the third opening 320_OP3 is expanded in the first direction, the sixth opening 325_OP3 may be formed. Additionally, as the first portion of the third opening 320_OP3 is expanded in the first direction, an expanded opening 325_OPE of the sixth opening 325_OP3 may be formed.

The second mask pattern 325 may include a second lower mask pattern 326 and a second upper mask pattern 327, which are sequentially formed on the hard mask film 310P. The second lower mask pattern 326 may be formed from the first lower mask pattern 321. The second upper mask pattern 327 may be formed from the first upper mask pattern 322.

By adjusting the shape of the first mask pattern 320 through the second etching process 345, the distance (L2) between the fourth and fifth openings 325_OP1 and 325_OP2 becomes less than the distance (L1) between the first and second openings 320_OP1 and 320_OP2. Thus, the spacing between connection wirings to be formed using the second mask pattern 325 can be reduced using the second mask pattern 325. Based on the embodiments of the present disclosure, not only the integration density, but also the performance and reliability of a semiconductor device can be improved.

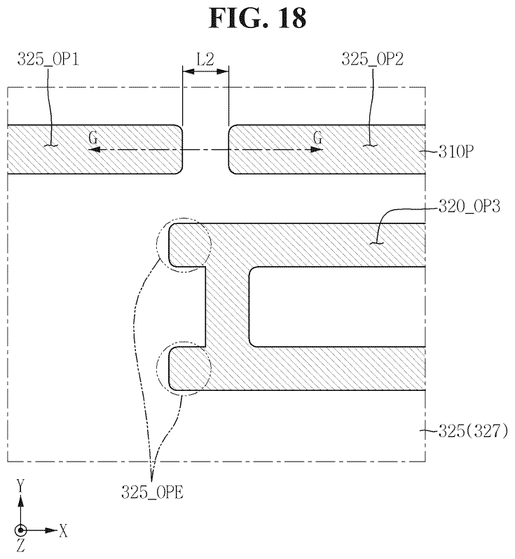

Referring to FIGS. 18 to 21, the hard mask film 310P may be patterned using the second mask pattern 325 as an etching mask in a third etching process, according to some embodiments.

As the hard mask film 310P is patterned, a hard mask pattern 310 may be formed. The hard mask pattern 310 may be formed on the second interlayer insulating film 230. The hard mask pattern 310 may expose the second interlayer insulating film 230.

The hard mask pattern 310 may include a seventh opening 310_OP1, an eighth opening 310_OP2, and a ninth opening 310_OP3. The seventh opening 310_OP1 may correspond to the fourth opening 325_OP1. The eighth opening 310_OP2 may correspond to the fifth opening 325_OP2. The ninth opening 310_OP3 may correspond to the sixth opening 325_OP3.

For example, the second mask pattern 325 may be removed after the formation of the hard mask pattern 310. In another example, the second mask pattern 325 may be removed during the formation of the hard mask pattern 310.

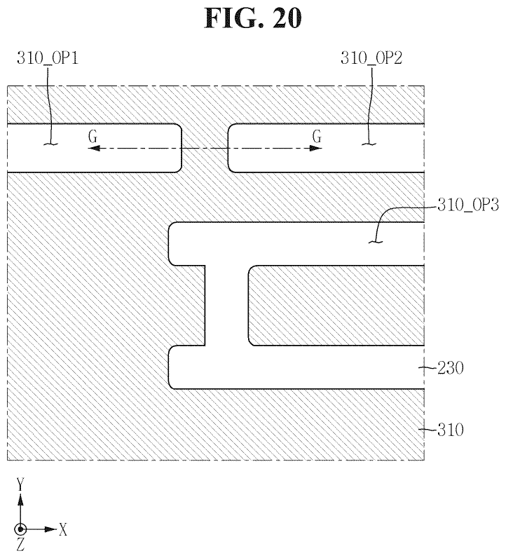

Referring to FIGS. 20 to 23, first, second, and third upper wiring trenches 210t, 220t, and 225t may be formed within the second interlayer insulating film 230 using the hard mask pattern 310 as an etching mask in a fourth etching process, according to some embodiments.

The first upper wiring trench 210t may be formed to correspond to the ninth opening 310_OP3. The second upper wiring trench 220t may be formed to correspond to the seventh opening 310_OP1. The third upper wiring trench 225t may be formed to correspond to the eighth opening 310_OP2.

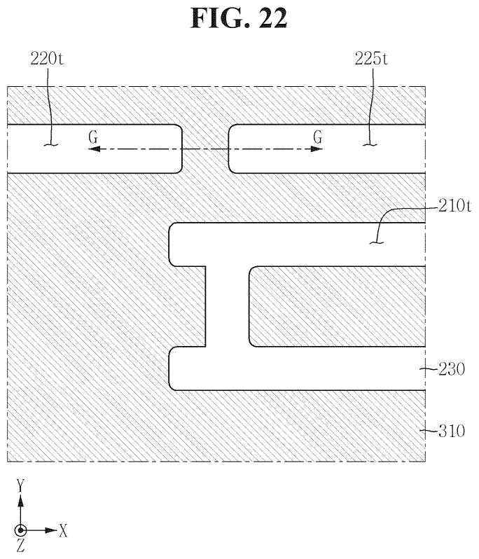

Referring to FIGS. 22 to 25, first through third upper connection wirings 210, 220, and 225 may be formed within the second interlayer insulating film 230, according to some embodiments.

The first upper connection wiring 210 may fill the first upper wiring trench 210t. The second upper connection wiring 220 may fill the second upper wiring trench 220t. The third upper connection wiring 225 may fill the third upper wiring trench 225t.

During the formation of the first, second, and third upper connection wirings 210, 220, and 225, the hard mask pattern 310 may be removed. The second and third upper connection wirings 220 and 225 may include an upper wiring barrier film 210a and an upper wiring fill film 210b.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor device comprising:
a first connection wiring and a second connection wiring in a first interlayer insulating film;
a second interlayer insulating film on the first interlayer insulating film;
a third connection wiring in the second interlayer insulating film;
a first connection via connecting the third connection wiring and the first connection wiring; and
a second connection via connecting the third connection wiring and the second connection wiring,
wherein the third connection wiring comprises:
a first line portion extending in a first direction and comprising a first sidewall and a second sidewall opposite to the first sidewall in a second direction;
a second line portion protruding from the first sidewall of the first line portion in the second direction; and
a first protruding portion protruding from the second sidewall of the first line portion in the second direction,
wherein the second line portion and the first protruding portion are aligned in the second direction, and
wherein the first connection via connects the second line portion and the first connection wiring.

2. The semiconductor device of claim 1, wherein the third connection wiring further comprises a third line portion protruding from the first sidewall of the first line portion in the second direction, and
wherein the third line portion overlaps the second line portion in the first direction.

3. The semiconductor device of claim 2, wherein the second connection via connects the third line portion and the second connection wiring.

4. The semiconductor device of claim 2, wherein the first line portion is not connected to the first connection via and the second connection via.

5. The semiconductor device of claim 2, wherein the third connection wiring further comprises a second protruding portion protruding from the second sidewall of the first line portion in the second direction, and
wherein the third line portion and the second protruding portion are aligned in the second direction.

6. The semiconductor device of claim 5, wherein the second protruding portion is not connected to the first connection via and the second connection via.

7. The semiconductor device of claim 1, wherein the third connection wiring further comprises a third line portion protruding from the second sidewall of the first line portion in the second direction, and
wherein the third line portion does not overlap with the second line portion in the first direction.

8. The semiconductor device of claim 7, wherein the third connection wiring further comprises a second protruding portion protruding from the first sidewall of the first line portion in the second direction, and
wherein the third line portion and the second protruding portion are aligned in the second direction.

9. The semiconductor device of claim 1, wherein the second connection via connects the first line portion and the second connection wiring.

10. The semiconductor device of claim 1, wherein the first protruding portion is not connected to the first connection via and the second connection via.

11. A semiconductor device comprising:
an interlayer insulating film;
a first connection wiring in the interlayer insulating film; and
one or more connection vias in the interlayer insulating film and connected to the first connection wiring,
wherein the first connection wiring comprises:
a first line portion extending in a first direction;
a second line portion and a third line portion, each of which are connected to the first line portion and extend in a second direction; and
a first protruding portion and a second protruding portion, each of which are connected to the first line portion and protrude in the second direction,
wherein the second line portion and the first protruding portion are aligned in the second direction,
wherein the third line portion and the second protruding portion are aligned in the second direction,
wherein the one or more connection vias overlap the second line portion and the third line portion in a third direction, and
the one or more connection vias do not overlap the first protruding portion and the second protruding portion in the third direction.

12. The semiconductor device of claim 11, wherein the second line portion overlaps the third line portion in the first direction.

13. The semiconductor device of claim 11, wherein a length of the second line portion in the second direction is greater than a length of the first protruding portion in the second direction, and
wherein a length of the third line portion in the second direction is greater than a length of the second protruding portion in the second direction.

14. The semiconductor device of claim 11, further comprising:
a second connection wiring disposed in the interlayer insulating film,
wherein the second connection wiring comprises:
a fourth line portion and a fifth line portion extending in the second direction; and
a sixth line portion connected to the fourth line portion and the fifth line portion.

15. The semiconductor device of claim 14, wherein the first connection wiring is between the fourth line portion and the fifth line portion of the second connection wiring.

16. The semiconductor device of claim 14, wherein the second connection wiring does not include a protruding portion protruding from the sixth line portion in the second direction.

17. A method of manufacturing a semiconductor device, comprising:
forming an interlayer insulating film on a substrate;
forming a hard mask film on the interlayer insulating film;
forming, on the hard mask film, a first mask pattern comprising a first opening and a second opening that are spaced apart from each other by a first distance;
forming, on the hard mask film using a first etching process that etches the first mask pattern, a second mask pattern that comprises a third opening and a fourth opening that are spaced apart from each other by a second distance that is less than the first distance;
forming a hard mask pattern on the interlayer insulating film by patterning the hard mask film using the second mask pattern; and
forming a first connection wiring trench and second connection wiring trench in the interlayer insulating film by performing a second etching process using the hard mask pattern,
wherein the first mask pattern comprises a first lower mask pattern and a first upper mask pattern, which are sequentially stacked on the hard mask film.

18. The method of claim 17, wherein the second mask pattern comprises a second lower mask pattern and a second upper mask pattern, which are sequentially stacked on the hard mask film.

19. The method of claim 17, wherein the first etching process comprises an ion beam etching process using an ion beam that is directed to the substrate at an oblique angle.

20. The method of claim 17, further comprising:
forming a first connection wiring and a second connection wiring, which fill the first connection wiring trench and the second connection wiring trench, respectively.
